(19) United States
(12) Patent Application Publication
(10) Pub. No.: US 2025/0357313 A1
(43) Pub. Date: Nov. 20, 2025

(54) EMBEDDED CAPACITORS WITH SHARED ELECTRODES

(71) Applicant: Taiwan Semiconductor Manufacturing Co., Ltd., Hsinchu (TW)

(72) Inventors: Meng-Hsien LIN, Tainan City (TW); Hsing-Chih Lin, Tainan City (TW); Ke Chun Liu, Miaoli (TW); Min-Feng Kao, Chiayi (TW); Kuan-Hua Lin, Taipei (TW)

(73) Assignee: Taiwan Semiconductor Manufacturing Co., Ltd., Hsinchu (TW)

(21) Appl. No.: 19/290,820

(22) Filed: Aug. 5, 2025

Related U.S. Application Data
(62) Division of application No. 17/842,972, filed on Jun. 17, 2022.

(51) Int. Cl. H01L 23/522; G06F 30/392; H10D 1/00; H10D 1/68

(52) U.S. Cl. CPC H01L 23/5223; G06F 30/392; H01L 23/5226; H10D 1/042; H10D 1/716

(57) ABSTRACT

Capacitors and interconnect structures that couple transistors to one another include parallel stacked metal lines separated by dielectric layers. When capacitors and interconnect structures are combined, each top metal capacitor plate can be coupled to the nearest upper metal line by a through-via, while each bottom metal capacitor plate can be coupled directly to the nearest lower metal line without a via. When a back end of line (BEOL) cell includes multiple capacitors, and design rules require shrinking the cell dimensions, substituting an alternative design that has fewer through-vias can facilitate compaction of the BEOL cell. Similarly, placing capacitors in close proximity so that they can share through-vias can allow even further compaction.

### CROSS-REFERENCE TO RELATED APPLICATIONS

This application is a divisional of U.S. patent application Ser. No. 17/842,972, titled “Embedded Capacitors with Shared Electrodes,” filed Jun. 17, 2022, which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of active semiconductor devices, such as metal oxide semiconductor field effect transistors (MOSFETs), including planar MOSFETs, fin field effect transistors (FinFETs), as well as capacitors. Such scaling down has increased the complexity of semiconductor manufacturing processes.

### BRIEF DESCRIPTION OF THE DRAWINGS

Aspects of the present disclosure are best understood from the following detailed description when read with the accompanying figures. It is noted that, in accordance with common practice in the industry, various features are not drawn to scale. In fact, the dimensions of the various features may be arbitrarily increased or reduced for clarity of discussion.

FIG. 1 is a cross-sectional view of a dual Metal-Insulator-Metal (MIM) capacitor, in accordance with some embodiments of the present disclosure.

FIGS. 2A and 2B are top plan views of MIM capacitors, in accordance with some embodiments of the present disclosure.

FIGS. 3A and 3B are top plan and cross-sectional views of a pair of single MIM capacitors, in accordance with some embodiments of the present disclosure.

FIGS. 4A and 4B are top plan and cross-sectional views of a pair of triple MIM capacitors, in accordance with some embodiments of the present disclosure.

FIGS. 5A and 5B are top plan and cross-sectional views of a dual MIM capacitor, in accordance with some embodiments of the present disclosure.

FIG. 6 is a flow diagram of a method for fabricating a dual MIM capacitor, in accordance with some embodiments of the present disclosure.

FIGS. 7-13 are cross-sectional views of the dual MIM capacitor shown in FIGS. 1 and 5B at various stages of its fabrication process, in accordance with some embodiments of the present disclosure.

FIG. 14 is an illustration of an integrated circuit manufacturing system and associated integrated circuit manufacturing flow, according to some embodiments of the present disclosure.

### DETAILED DESCRIPTION

The following disclosure provides different embodiments, or examples, for implementing different features of the provided subject matter. Specific examples of components and arrangements are described below to simplify the present disclosure. These are, of course, merely examples and are not intended to be limiting. For example, the formation of a first feature on a second feature in the description that follows may include embodiments in which the first and second features are formed in direct contact, and may also include embodiments in which additional features may be formed that are between the first and second features, such that the first and second features are not in direct contact.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “nominal” as used herein refers to a desired, or target, value of a characteristic or parameter for a component or a process operation, set during the design phase of a product or a process, together with a range of values above and/or below the desired value. The range of values can be due to slight variations in manufacturing processes or tolerances.

In some embodiments of the present disclosure, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

The term “vertical,” as used herein, means perpendicular to the surface of a substrate.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Parallel plate capacitors can be inserted into the back end of line (BEOL) of a semiconductor process. Like capacitors, interconnect structures that couple transistors to one another include parallel stacked metal lines separated by dielectric layers. When the two are combined, each top metal capacitor plate can be coupled to the nearest upper metal line by a through via, and each bottom metal capacitor plate can be coupled directly to the nearest lower metal line. When a capacitor is formed as a separate and distinct structure with its own through-via (TV) connection, such a design may not allow for sufficient compaction. On the other hand, if a BEOL structure includes multiple capacitors and design rules require shrinking the dimensions, substituting an alternative design that has fewer through-vias may facilitate compaction of the BEOL structure. Similarly, placing capacitors in close proximity so that they can share through-vias can allow even further compaction.

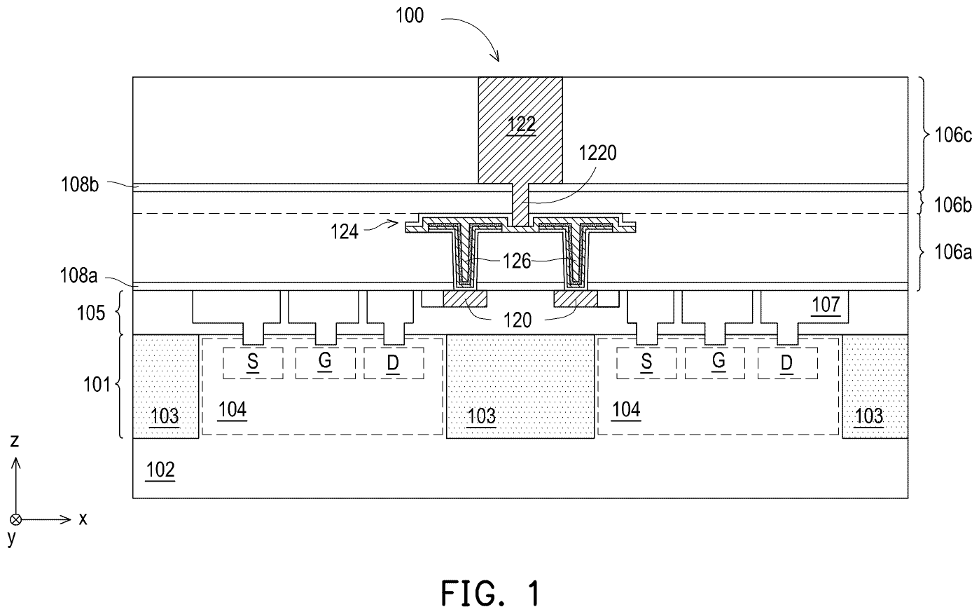

FIG. 1 shows a dual MIM capacitor 124 embedded within a metal interconnect structure 100, according to some embodiments. Metal interconnect structure 100 is fabricated above an electronic device, e.g., a transistor structure 101 that is integrated into a semiconductor substrate 102. Metal interconnect structure 100 is coupled to transistor structure 101 by a contact structure 105. As used herein, the term “substrate” describes a material onto which subsequent material layers are added. Substrate 102 itself may be patterned. Materials added onto substrate 102 may be patterned or may remain unpatterned.

Substrate 102 can be a bulk semiconductor wafer or the top semiconductor layer of a semiconductor-on-insulator (SOI) wafer (not shown), such as silicon-on-insulator. In some embodiments, substrate 102 can include a crystalline semiconductor layer with its top surface parallel to (100), (110), (111), or c-(0001) crystal plane. Substrate 102 can be made of a semiconductor material such as, but is not limited to, silicon (Si). Alternatively, substrate 102 may be made from an electrically non-conductive material, such as a glass or sapphire wafer, or a plastic substrate.

In some embodiments, substrate 102 can include (i) an elementary semiconductor, such as germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 102 can be doped with p-type dopants (e.g., boron (B), indium (In), aluminum (Al), or gallium (Ga)) or n-type dopants (e.g., phosphorus (P) or arsenic (As)). In some embodiments, different portions of substrate 102 can have opposite type dopants.

Transistor structure 101 includes isolation regions 103 and transistors 104, each formed with a source S, gate G, and drain D, as illustrated schematically in FIG. 1. Transistors 104 are electrically isolated from one another by isolation regions 103, e.g., shallow trench isolation (STI) regions 103. In some embodiments, transistors 104 can be, for example, bipolar junction transistors (BJTs), planar metal oxide semiconductor field effect transistors (MOSFETs), or three-dimensional MOSFETs, such as FinFETs, nanowire FETs, gate-all-around FETs (GAAFETs), or combinations thereof.

STI regions 103 can be formed adjacent to, or between transistors 104. STI regions 103 can be deposited and then etched back to a desired height. Insulating material in STI regions 103 can include, for example, silicon oxide (SiO₂), silicon nitride (SiN), silicon oxynitride (SiON), fluoride-doped silicate glass (FSG), a low-k dielectric material, and/or other suitable insulating material. In some embodiments, the term “low-k” refers to a low dielectric constant. In the field of semiconductor device structures and manufacturing processes, low-k refers to a dielectric constant that is less than the dielectric constant of SiO₂ (e.g., less than 3.9). In some embodiments, STI regions 103 can include a multi-layered structure. In some embodiments, the process of depositing the insulating material can include any deposition method suitable for flowable dielectric materials (e.g., flowable silicon oxide). For example, flowable silicon oxide can be deposited for STI regions 103 using a flowable chemical vapor deposition (FCVD) process. The FCVD process can be followed by a wet anneal process. In some embodiments, the process of depositing the insulating material can include depositing a low-k dielectric material to form a liner. In some embodiments, a liner made of another suitable insulating material can be placed between STI region 103 and adjacent transistors 104. In some embodiments, STI regions 103 may be annealed and polished to be co-planar with a top surface of transistors 104. The anneal process can be followed by a polishing process that can remove a surface layer of the insulating material. The polishing process can be followed by the etching process to recess the polished insulating material to form STI regions 103.

Between metal interconnect structure 100 and transistor structure 101 lies a contact structure 105 that provides electrical connections between transistors 104 and metal interconnect structure 100. The process of forming contact structure 105 can include forming metal silicide layers and/or conductive regions within contact openings that couple to source, gate, and drain terminals of transistors 104. In some embodiments, the metal used to form metal silicide layers of contact structure 105 can include one or more of tungsten (W), cobalt (Co), titanium (Ti), and nickel (Ni). In some embodiments, contact metal is deposited by atomic layer deposition (ALD) or chemical vapor deposition (CVD) to form diffusion barrier layers (not shown) along surfaces of contact structure 105. This deposition of diffusion barrier layers can be followed by a high temperature rapid thermal annealing (RTA) process to form metal silicide layers.

The process of forming conductive regions of contact structure 105 can include deposition of a conductive material followed by a polishing process to co-planarize top surfaces of the conductive regions with top surfaces of insulating material surrounding contact structure 105. The conductive materials can be one or more of W, Al, Co, Cu, Ti, gold (Au), silver (Ag), or another suitable conductive material, a metal alloy, or a stack of various metals or metal alloys that may include layers, such as a TiN layer. The conductive materials can be deposited by, for example, plasma vapor deposition (PVD), CVD, or ALD. The polishing process for co-planarizing the conductive region with the top surface of contact structure 105 can be a chemical mechanical planarization (CMP) process. In some embodiments, the CMP process can use a silicon or an aluminum abrasive slurry with abrasive concentrations ranging from about 0.1% to about 3%. In some embodiments, the abrasive slurry may have a pH level less than 7 for W metal, or a pH level greater than 7 for Co or Cu metals in the conductive regions.

Referring to FIG. 1, interconnect structure 100 includes a first pair of metal lines 120 formed in contact structure 105, a blocking structure (or etch stop layer 108a), a first inter-layer dielectric (ILD) 106a, and an upper metal line 122, according to some embodiments. In some embodiments, bottom capacitor plates of dual MIM capacitor 124 can be connected directly to respective lower metal lines 120, while upper metal line 122 is coupled to a shared top electrode of dual MIM capacitor 124 by a single electrical path in the form of a via 1220.

Dual MIM capacitor 124 can be formed by a top capacitor plate, a bottom capacitor plate, and a high-k dielectric material between the top and bottom capacitor plates. Insulators 106a, 106b, and 106c can be made of the same or different materials, and can have similar or different thicknesses. In the example shown in FIG. 1, dual MIM capacitor 124 has a shared top capacitor plate, while bottom capacitor plates are distinct. Other configurations can be used for dual MIM capacitor 124. For example, the top capacitor plate could be split into two separate top capacitor plates, while combining bottom capacitor plates into one capacitor plate. Or, the top and bottom plates of dual MIM capacitor 124 can both be shared. Dual MIM capacitor 124 is adjacent to low-k interconnect structures that include vias and metal lines. Interconnect structure 100 represents a portion of a larger interconnect structure that may include additional metal lines than the metal lines shown in FIG. 1, e.g., metal lines 120 and 122. Dual MIM capacitor 124 can be formed between any two successive metal layers, e.g., between metal layer M1 and metal layer M2, between metal layer M2 and metal layer M3, and so on. Alternatively, dual MIM capacitor 124 can also be formed between pairs of metal lines above metal line 122.

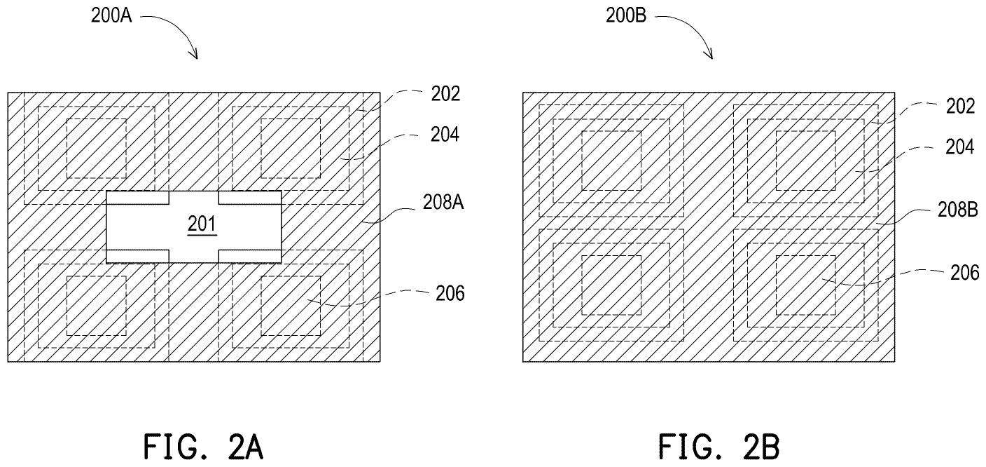

FIGS. 2A and 2B show top plan views of two different layouts for capacitor cells, 200A and 200B, within an integrated circuit design, according to some embodiments. The integrated circuit design cell layouts show various components as transparent rectangular areas representing planes at different levels along the z-axis. Each rectangular area corresponds to a footprint of a structure, such as an electrode or an electrical contact. The various footprints indicate relative sizes of the structures, which are shown in cross-section in subsequent figures. FIG. 2A shows a capacitor cell 200A in which four parallel plate capacitors are arranged around a central square space 201. Each capacitor has a lower electrode (or capacitor bottom metal (CBM)) 202 and an upper electrode (or capacitor top metal (CTM)) 204. In some embodiments CTM 204 as viewed from the top is smaller than the footprint of CBM 202. Each capacitor is coupled by a through-via (TV) 206 to a top metal line (TM) 208A. The footprint of top metal line 208A surrounds central square space 201. FIG. 2B shows a compact or “shrink” capacitor cell 200B in which four capacitors are arranged in a closer proximity to one another—as compared to capacitor cell 200A—with no central square space. In FIG. 2B, upper metal line 208B is in the shape of a square pad that occupies all of the area above the four capacitors.

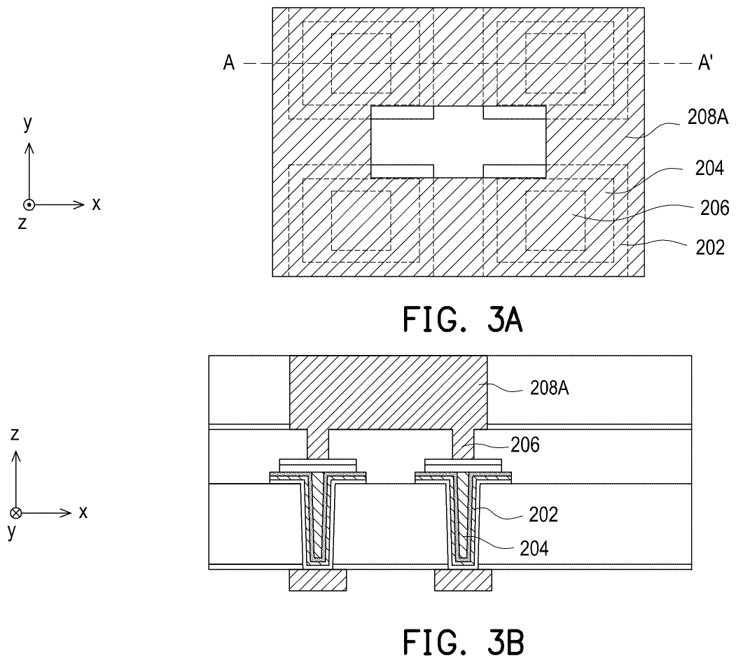

FIG. 3A reproduces a central portion of the top plan view of capacitor cell 200A shown in FIG. 2A, according to some embodiments. FIG. 3B shows a corresponding cross-sectional view of capacitor cell 200A along cut line A-A′ indicated in FIG. 3A, according to some embodiments. FIG. 3B shows two T-shaped MIM capacitors, each capacitor having its own through-via TV 206 to connect it to top metal line TM 208A. This arrangement occupies additional chip area, due to the dedicated through-vias TV 206.

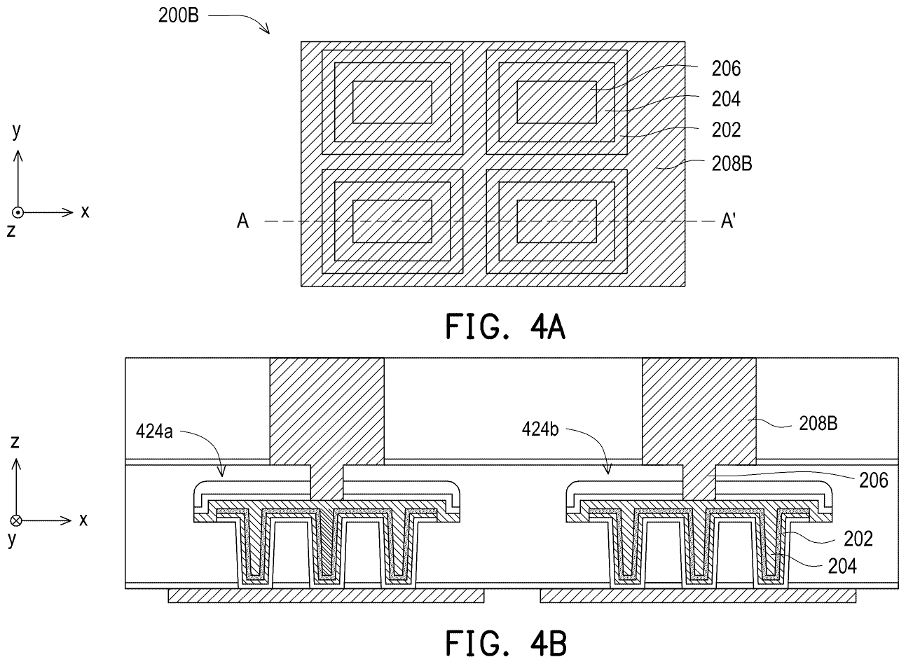

FIG. 4A reproduces a top plan view of shrink capacitor cell 200B shown in FIG. 2B, according to some embodiments. FIG. 4B shows a corresponding cross-sectional view of shrink capacitor cell 200B along cut line A-A′ indicated in FIG. 4A, according to some embodiments. FIG. 4B shows that, in an implementation of shrink capacitor cell 200B, each TV 206 connects to a group of three capacitors that share a common CTM, and the CBMs are also coupled together. Thus, in this embodiment, there are six MIM capacitors in the same space formerly occupied by two capacitors in cell capacitor 200A. In some embodiments, as shown in FIG. 4B, the six MIM capacitors are in the form of two triple MIM capacitors 424a and 424b. In the example shown, triple MIM capacitors 424a and 424b are each coupled to top metal line TM 208B by a shared TV 206. Triple MIM capacitors 424a and 424b are each coupled to respective bottom metal lines by direct contact with CBM 204.

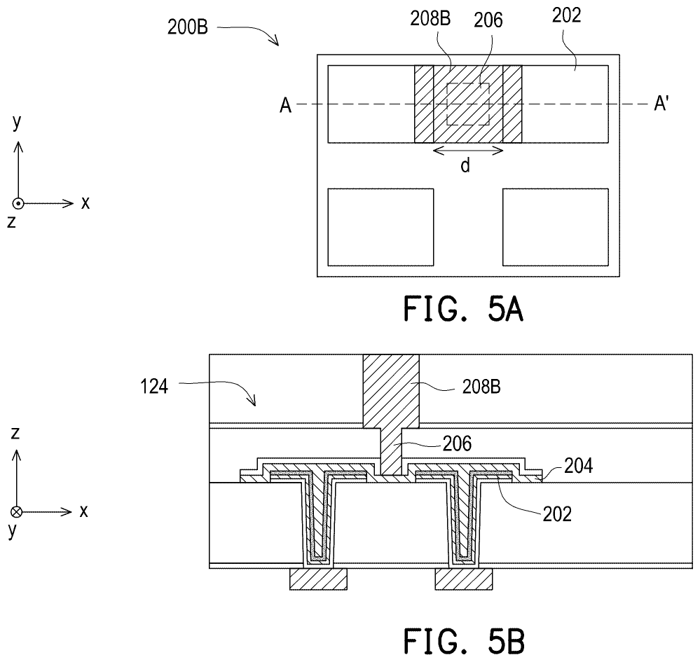

FIG. 5A reproduces a top plan view of shrink capacitor cell 200B shown in FIG. 2B, according to some embodiments. FIG. 5A shows the following: first and second rectangular areas corresponding to first and second capacitors 202 spaced apart by a separation distance d; a third rectangular area 208B overlapping the first and second rectangular areas, where third rectangular area 208B corresponds to a metal line; and a fourth rectangular area 206 within third rectangular area 208B, where fourth rectangular area 206 corresponds to a via 206 configured to provide a shared electrical path from the metal line to first and second capacitors 202. In some embodiments, the footprint of via 206 fits within the separation distance d. In some embodiments of shrink capacitor cell 200B, the footprint of the metal line 208B can be smaller than the footprint of first and second capacitors 202.

FIG. 5B shows a corresponding cross-sectional view of shrink capacitor cell 200B along cut line A-A′ indicated in FIG. 5A, according to some embodiments. FIG. 5B shows that, in another implementation of shrink capacitor cell 200B, each TV 206 connects to a pair of capacitors that share a common CTM, using one TV 206, while the CBMs are also coupled to different bottom metal lines. Thus, in this embodiment, there are two capacitors in the form of a dual MIM capacitor, occupying a smaller area than the pair of capacitors of cell capacitor 200A, which uses separate TVs.

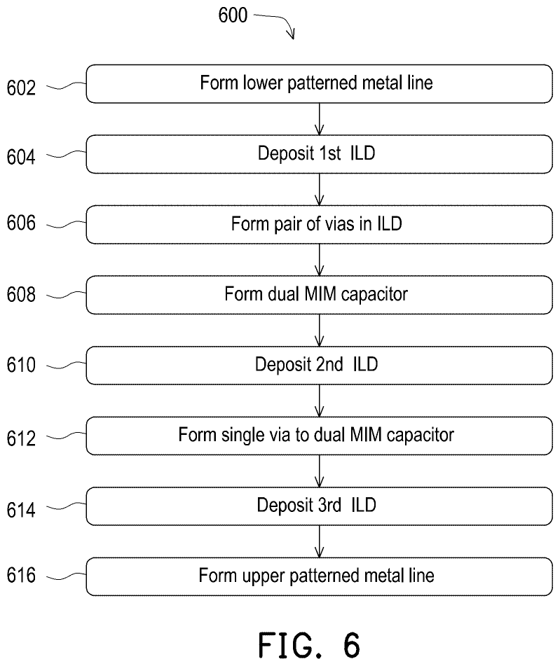

FIG. 6 presents a method 600 of fabricating a dual MIM capacitor embedded between two metal lines vertically adjacent to one another, according to some embodiments. In some embodiments, method 600 can be used to fabricate shrink cell capacitor 200B of FIG. 5B. For illustrative purposes, the operations of method 600 will be described with reference to FIGS. 1 and 7-13. The operations of method 600 are also applicable to other MIM capacitor structures. Some of the operations of method 600 can be performed simultaneously or in a different order. It should be noted that method 600 may not produce a complete device. Accordingly, it is understood that additional operations can be provided before, during, and after method 600, and that some other operations may only be briefly described herein.

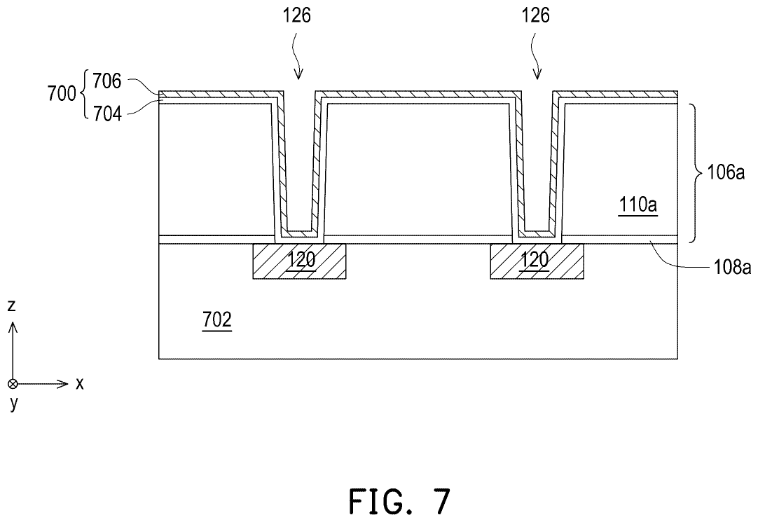

Turning now to FIG. 6, in operation 602, lower metal lines 120 are formed on a substrate 702, as shown in FIG. 7. Substrate 702 represents a structure underlying lower metal lines 120. In some embodiments, substrate 702 includes transistor structure 101 (not shown), in which transistors 104 have been formed. In some embodiments, lower patterned metal lines 120 are formed in contact structure 105 (not shown). Alternatively, lower patterned metal lines 120 can be in any metal layer, e.g., metal layer M1, metal layer M2, etc, except for a topmost metal layer.

In some embodiments, lower patterned metal lines 120 can be made of aluminum (Al) or an aluminum copper alloy (AlCu), and fabricated using a subtractive process. In some embodiments, lower patterned metal lines 120 can be formed by depositing a metal layer, using a lithography process to pattern the metal layer, and etching the metal layer according to the lithography pattern. In some embodiments, lower metal lines 120 can be made of copper (Cu), and can be fabricated using a damascene process. In a damascene process, trenches are formed in the underlying substrate 702, e.g., in an insulating layer, and the trenches are then filled with a conductor, e.g., copper, to form lower metal lines 120, using, for example, a metal plating process.

Referring to FIG. 6, in operation 604, first ILD 106a is deposited over lower metal lines 120, as shown in FIG. 7, according to some embodiments. In some embodiments, first ILD 106a includes an etch stop layer 108a made of silicon nitride (SiN) or silicon carbide (SiC). Etch stop layer 108a can have a thickness in a range of about 30 nm to about 100 nm. In some embodiments, the thickness of etch stop layer 108a can be in the range of about 50 nm to about 60 nm. First ILD 106a further includes a bulk oxide 110a, e.g., silicon dioxide (SiO₂), having a thickness in a range of about 180 nm to about 220 nm. In some embodiments, bulk oxide 110a can be deposited using a plasma enhanced chemical vapor deposition (PECVD) process.

Referring to FIG. 6, in operation 606, trenches 126 are formed in ILD 106a, as shown in FIG. 7. Trenches 126 can be etched through the full thickness of ILD 106a, stopping on etch stop layer 108a, and then over-etching through etch stop layer 108a. Trenches 126 can be tapered such that the widths of trenches 126 are wider at the top of ILD 106a and narrower at the bottom. In some embodiments, trenches 126 can have aspect ratios (depth:width) in a range of about 45:1 to about 55:1. When trenches 126 have aspect ratios below about 45:1, a direct connection to lower metal lines 120 may be compromised, resulting in an open circuit. When trenches 126 have aspect ratios exceeding about 55:1 the fill process may be incomplete. Trenches 126 can be aligned to land on, and expose, lower metal lines 120. The etch chemistry used to form trenches 126 can include, for example, a fluorine-based plasma mixed with a neutral gas containing atoms, such as argon (Ar). Trenches 126 are arranged so they will electrically couple one electrode of each of the capacitors in the final dual MIM capacitor 124 to a separate metal line 120, to maintain independent selectivity of each of the capacitors.

Referring to FIG. 6, in operation 608, dual MIM capacitor 124 (FIG. 5B can be formed over ILD 106a, as shown in FIGS. 7-11. Dual MIM capacitor 124 is a T-shaped parallel plate capacitor that includes a capacitor bottom metal (CBM) 700, a capacitor top metal (CTM) 1000, and a capacitor dielectric 800 sandwiched between CBM 700 and CTM 1000. When patterned, CBM 700 corresponds to CBM 202 and CTM 1000 corresponds to CTM 204 in the design of FIGS. 2A-5B.

Referring to FIG. 7, CBM 700 of dual MIM capacitor 124 is conformally deposited on the surface of ILD 106a, and extends conformally into trenches 126, to form electrical contact with lower metal lines 120. Dual MIM capacitor 124 therefore is non-planar as opposed to forming a flat plate electrode as in other capacitor designs. In the present embodiment, dual MIM capacitor has a T-shape that allows CBM 700 to contact lower metal lines 120 directly without an intervening via structure. In some embodiments, a metal plating process can be used to deposit CBM 700 into trenches 126. In some embodiments, CBM 700 is a multi-layer metal stack that includes a bottom CBM layer 704 and a top CBM layer 706. In some embodiments, bottom CBM layer 704 serves as a barrier film. In some embodiments, bottom CBM layer 704 is made of titanium (Ti), tantalum (Ta), or tantalum nitride (TaN), or combinations thereof, having a total thickness in a range of about 135 Å to about 150 Å. In some embodiments, top CBM layer 706 is made of titanium nitride (TiN), having a thickness in a range of about 180 Å to about 220 Å. When the thickness of CBM 700 is out of range, gapfill within trench 126 may be insufficient. Lower metal lines 120 thus will provide separate electrical contacts to each of the lower capacitor plates CBM 700 of the two capacitors making up dual MIM capacitor 124.

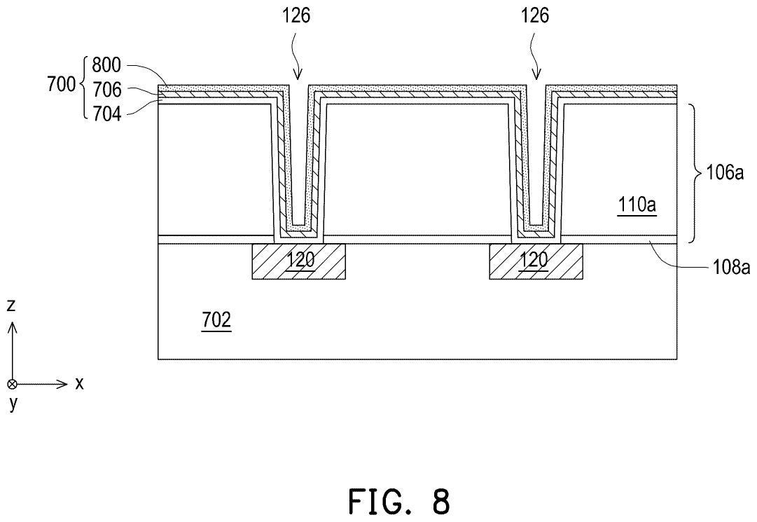

Referring to FIG. 8, capacitor dielectric 800 can be conformally deposited, e.g., by atomic layer deposition (ALD), into high aspect ratio trenches 126 on top of CBM 700. In some embodiments, capacitor dielectric 800 includes sub-layers of multiple materials that, together, form a high-k (high dielectric constant), composite material. In some embodiments, capacitor dielectric 800 includes one or more of hafnium oxide (HfO₂) and titanium oxide (TiO₂). In some embodiments, capacitor dielectric 800 is made of aluminum oxide (Al₂O₃) sandwiched between two layers of zirconium (Zr), sometimes referred to as “ZAZ,” where each of the three layers has a thickness in a range of about 18 Å to about 22 Å. In some embodiments, the total thickness of capacitor dielectric 800 is in the range of about 2 nm to 120 nm. When the thickness of capacitor dielectric 800 is below the desired range, there is a risk of dielectric breakdown during operation of dual MIM capacitor 124. When the thickness of capacitor dielectric 800 is above the desired range, the capacitance, or capacitance per unit area, may be too small to be practical.

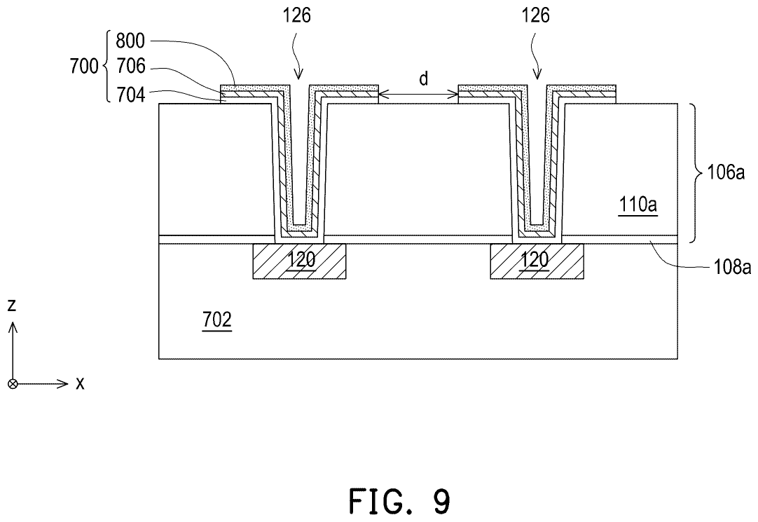

Referring to FIG. 9, CBM 700 and capacitor dielectric 800 can be patterned to remove portions of CBM 700 and capacitor dielectric 800, including material located between trenches 126, so that the bottom electrodes of the capacitors making up dual MIM capacitor 124 will not be electrically connected. Separating the bottom electrodes by a separation distance d can be achieved by patterning a hard mask (not shown) with photoresist, etching through all three layers of capacitor dielectric 800 and CBM 700, and then removing the hard mask. In some embodiments, the separation distance d can be in the range of about 0.05 μm to about 5 μm. When separation distance d exceeds the desired range, there is a risk that the cell design requirements may not be met. On the other hand, because separation distance d also defines the width of a subsequent via connection to CTM 1000, when separation distance d is below a minimum value, an aspect ratio of the via connection may be challenging to fill, resulting in a high via resistance. Also, if the separation distance d is below a minimum value, a short circuit may occur between the two bottom electrodes of dual MIM capacitor 124.

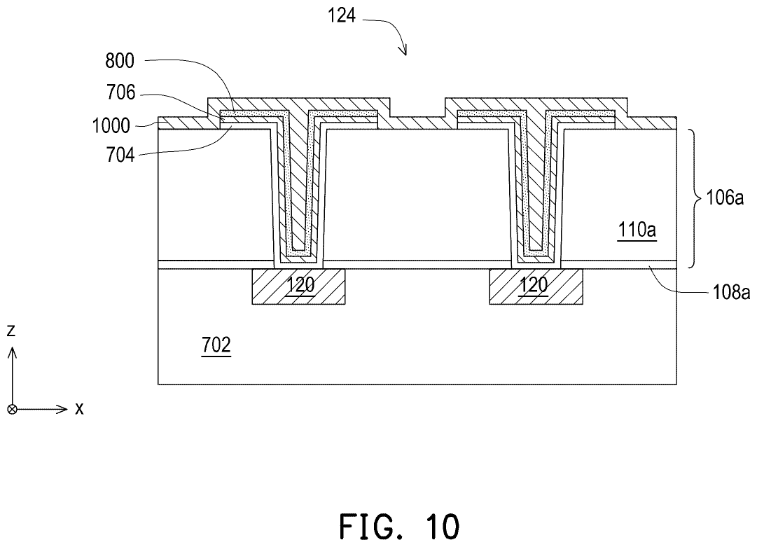

Referring to FIG. 10, CTM 1000 can be conformally deposited over capacitor dielectric 800 to complete formation of dual MIM capacitor 124. Like CBM 700 and capacitor dielectric 800, CTM 1000 extends into trenches 126 to fill trenches 126. In some embodiments, a metal plating process can be used to deposit CTM 1000 into trenches 126. In some embodiments, CTM 1000 is made of TiN having a thickness in a range of about 36 nm to about 44 nm. If the CTM thickness is outside this range, the pattern loading on etch chemistry can be affected. When a pattern shrink is performed, this effect can be exaggerated. CTM 1000 extends over both trenches 126 to form a shared top electrode, thus facilitating a parallel electrical connection between the two capacitors of dual MIM capacitor 124. CTM 1000 can be deposited using, for example, a metal plating process.

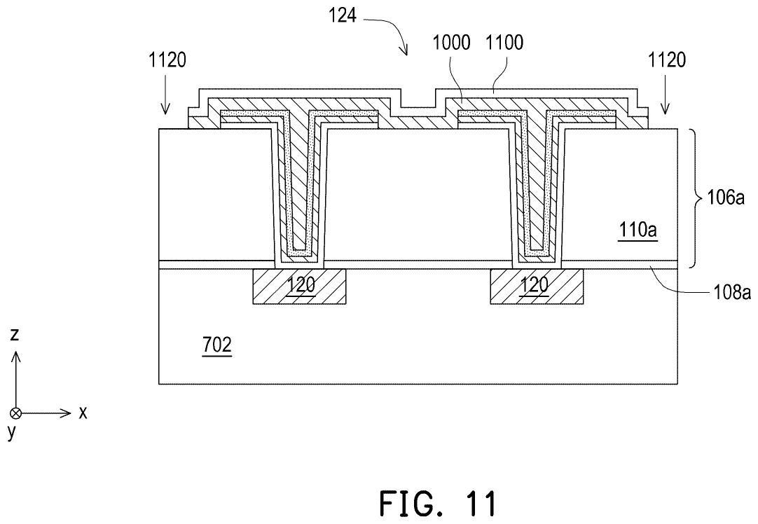

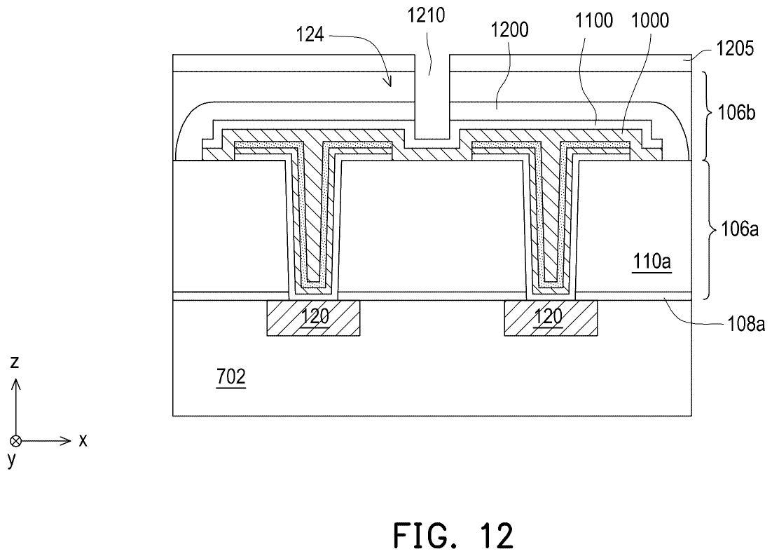

Referring to FIG. 11 and FIG. 12, CTM 1000 can be patterned using a hard mask 1100. Portions 1120 of CTM 1000 that are outside the area occupied by dual MIM capacitor 124 can then be removed to isolate dual MIM capacitor 124 from neighboring devices. Isolating dual MIM capacitor 124 can be achieved by patterning hard mask 1100 using photoresist, and etching through CTM 1000 and capacitor dielectric 800, in a similar way as is described above for patterning CBM 700. Hard mask 1100 may be removed or left in place as a passivation layer. Additionally or alternatively, a separate passivation layer 1200 can be conformally deposited on top of CTM 1000, and passivation layer 1200 can be patterned along with CTM 1000. Formation of CTM 1000 thus completes the dual MIM capacitor 124.

Referring to FIG. 6, in operation 610, a second ILD layer 106b can be deposited over passivation layer 1200 as shown in FIG. 12. In some embodiments, second ILD layer 106b has similar characteristics (e.g., material, thickness) to first ILD 106a, as described above, except that second ILD layer 106b does not include an etch stop layer.

Referring to FIG. 6, in operation 612, second ILD layer 106b can be patterned, using a mask 1205, e.g., a photoresist mask or a hard mask, to etch a via opening 1210 in second ILD layer 106b, as shown in FIG. 12. In some embodiments, via opening 1210 extends through passivation layer 1200, if present, and hard mask 1100 into CTM 1000, landing about midway between the two T-shaped MIM capacitors of dual MIM capacitor 124. When via opening 1210 is filled with metal in a subsequent step, e.g., by a dual damascene plating process, the resulting via 1220 can provide an electrical contact to the shared top electrode of dual MIM capacitor 124. After via opening 1210 is formed, mask 1205 can be removed from second ILD layer 106b.

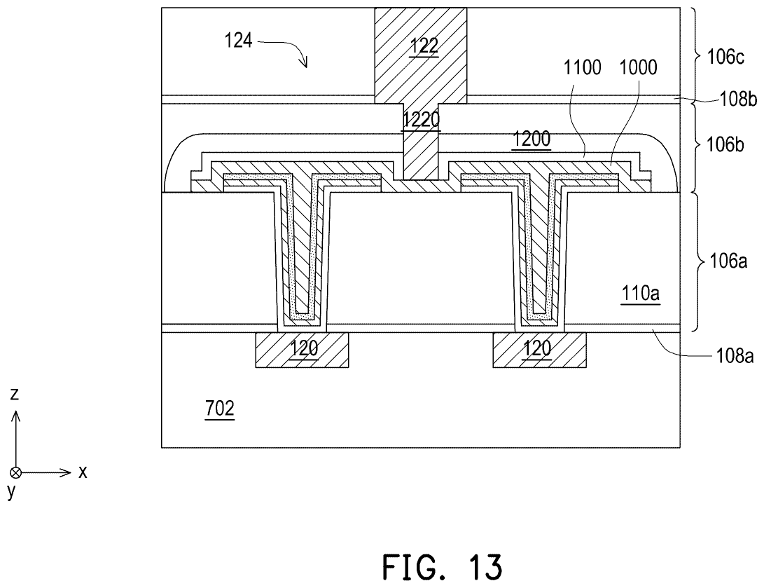

Referring to FIG. 6, in operation 614, third ILD layer 106c can be deposited, as shown in FIG. 13. In some embodiments, third ILD layer 106c has similar characteristics (e.g., material and thickness) to first and second ILD layers 106a and 106b, as described above. In some embodiments, third ILD layer 106c includes an etch stop layer 108b.

Referring to FIG. 6, in operation 616, upper patterned metal line 122 can be formed, as shown in FIG. 13. In some embodiments, third ILD layer 106c is patterned with a photoresist mask or a hard mask to etch a metal line trench through both third ILD layer 106c and etch stop layer 108b to connect with via opening 1210. Then, the metal line trench and via opening 1210 can be filled with metal, e.g., copper, using a dual damascene plating process, to form upper metal line 122 and via 1220 as shown in FIG. 13. Thus, dual MIM capacitor 124 is available as a three-terminal device accessible between adjacent lower and upper metal lines 120 and 122, respectively. Via 1220, corresponding to rectangular area TV 206 in design FIGS. 2A-5B, provides an electrical path to the shared top electrode, CTM 1000, thus allowing for compaction of shrink capacitor cell 200B.

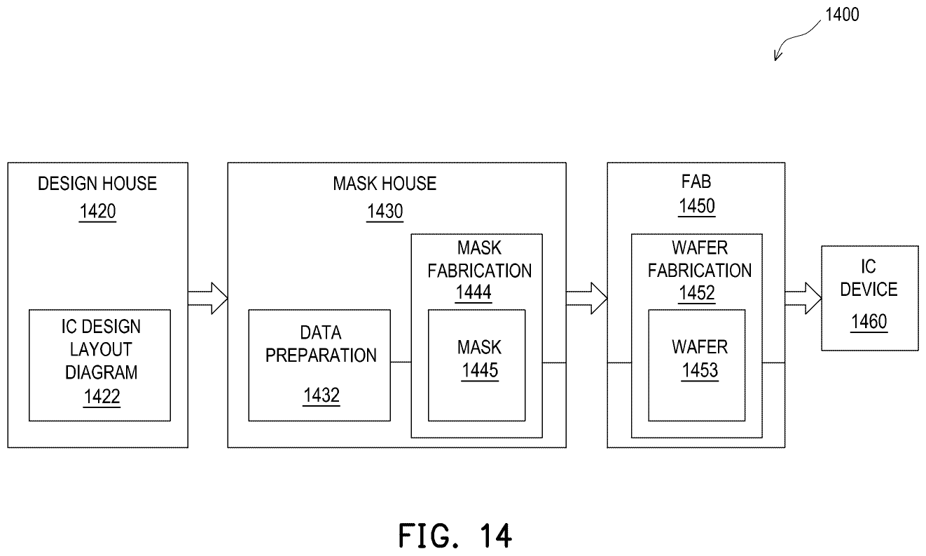

FIG. 14 is an illustration of an integrated circuit (IC) manufacturing system 1400 and associated integrated circuit manufacturing flow, according to some embodiments of the present disclosure. In some embodiments, based on a layout diagram, at least one of one or more semiconductor masks or at least one component in a layer of a semiconductor integrated circuit (e.g., shrink capacitor cell 200B) is fabricated using IC manufacturing system 1400.

In FIG. 14, IC manufacturing system 1400 includes entities, such as a design house 1420, a mask house 1430, and an IC manufacturer/fabricator (“fab”) 1450, that interact with one another in the design, development, and manufacturing cycles and/or services related to manufacturing an IC device 1460 (e.g., shrink capacitor cell 200B). The entities in IC manufacturing system 1400 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1420, mask house 1430, and IC fab 1450 is owned by a single entity. In some embodiments, two or more of design house 1420, mask house 1430, and IC fab 1450 coexist in a common facility and use common resources.

Design house (or design team) 1420 generates an IC design layout diagram 1422. IC design layout diagram 1422 includes various geometrical patterns—for example, e.g., shrink capacitor cell 200B designed for an IC device 1460. The geometrical patterns correspond to patterns of metal, oxide, or semiconductor layers that make up the various components of IC device 1460 to be fabricated. The various layers combine to form various IC features. For example, a portion of IC design layout diagram 1422 includes various IC features, such as an active region, gate electrode, source and drain, conductive segments or vias of an interlayer interconnection, to be formed in a semiconductor substrate (such as a silicon wafer) and various material layers disposed on the semiconductor substrate. Design house 1420 implements a proper design procedure to form IC design layout diagram 1422. The design procedure includes one or more of logic design, physical design or place and route. IC design layout diagram 1422 is presented in one or more data files having information of the geometrical patterns. For example, IC design layout diagram 1422 can be expressed in a GDSII file format or DFII file format.

Mask house 1430 includes data preparation 1432 and mask fabrication 1444. Mask house 1430 uses IC design layout diagram 1422 to manufacture one or more masks 1445 to be used for fabricating the various layers of IC device 1460 according to IC design layout diagram 1422. Mask house 1430 performs mask data preparation 1432, where IC design layout diagram 1422 is translated into a representative data file (“RDF”). Mask data preparation 1432 provides the RDF to mask fabrication 1444. Mask fabrication 1444 includes a mask writer. The mask writer converts the RDF to an image on a substrate, such as a mask (reticle) 1445 or a semiconductor wafer 1453. The IC design layout diagram 1422 is manipulated by mask data preparation 1432 to comply with particular characteristics of the mask writer and/or requirements of IC fab 1450. In FIG. 14, data preparation 1432 and mask fabrication 1444 are illustrated as separate elements. In some embodiments, data preparation 1432 and mask fabrication 1444 can be collectively referred to as “mask data preparation.”

In some embodiments, data preparation 1432 includes optical proximity correction (OPC) which uses lithography enhancement techniques to compensate for image errors, such as those that can arise from diffraction, interference, and other process effects. OPC adjusts IC design layout diagram 1422. In some embodiments, data preparation 1432 includes further resolution enhancement techniques (RET), such as off-axis illumination, sub-resolution assist features, phase-shifting masks, other suitable techniques, or combinations thereof. In some embodiments, inverse lithography technology (ILT) can also be used, which treats OPC as an inverse imaging problem.

In some embodiments, data preparation 1432 includes a mask rule checker (MRC) that checks the IC design layout diagram 1422 that has undergone processes in OPC with a set of mask creation rules which contain certain geometric and/or connectivity restrictions to ensure sufficient margins and to account for variability in semiconductor manufacturing processes. In some embodiments, the MRC modifies the IC design layout diagram 1422 to compensate for limitations during mask fabrication 1444, which may undo part of the modifications performed by OPC in order to meet mask creation rules.

In some embodiments, data preparation 1432 includes lithography process checking (LPC) that simulates processing that will be implemented by IC fab 1450 to fabricate IC device 1460. LPC simulates this processing based on IC design layout diagram 1422 to create a simulated manufactured device, such as IC device 1460. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, or combinations thereof. In some embodiments, after a simulated manufactured device has been created by LPC, if the simulated device is not close enough in shape to satisfy design rules, OPC and/or MRC can be repeated to further refine IC design layout diagram 1422.

It should be understood that the above description of data preparation 1432 has been simplified for the purposes of clarity. In some embodiments, data preparation 1432 includes additional features, such as a logic operation (LOP) to modify the IC design layout diagram 1422 according to manufacturing rules. Additionally, the processes applied to IC design layout diagram 1422 during data preparation 1432 can be executed in a variety of different orders.

After data preparation 1432 and during mask fabrication 1444, a mask 1445 or a group of masks 1445 are fabricated based on the modified IC design layout diagram 1422. In some embodiments, mask fabrication 1444 includes performing one or more lithographic exposures based on IC design layout diagram 1422. In some embodiments, an electron-beam (e-beam) or a mechanism of multiple e-beams is used to form a pattern on a mask (photomask or reticle) 1445 based on the modified IC design layout diagram 1422. Mask 1445 can be formed in various technologies. In some embodiments, mask 1445 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1445 includes a transparent substrate (e.g., fused quartz) and an opaque material (e.g., chromium) coated in the opaque regions of the binary mask. In another example, mask 1445 is formed using a phase shift technology. In a phase shift mask (PSM) version of mask 1445, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1444 is used in a variety of processes. For example, such a mask(s) is used in an ion implantation process to form various doped regions in semiconductor wafer 1453, in an etching process to form various etching regions in semiconductor wafer 1453, and/or in other suitable processes.

IC fab 1450 includes wafer fabrication 1452. IC fab 1450 is an IC fabrication business that includes one or more manufacturing facilities for the fabrication of a variety of different IC products. In some embodiments, IC fab 1450 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1450 uses mask(s) 1445 fabricated by mask house 1430 to fabricate IC device 1460. Thus, IC fab 1450 at least indirectly uses IC design layout diagram 1422 to fabricate IC device 1460. In some embodiments, semiconductor wafer 1453 is fabricated by IC fab 1450 using mask(s) 1445 to form IC device 1460. In some embodiments, the IC fabrication includes performing one or more lithographic exposures based at least indirectly on IC design layout diagram 1422. Semiconductor wafer 1453 includes a silicon substrate or other proper substrate having material layers formed thereon. Semiconductor wafer 1453 further includes one or more of various doped regions, dielectric features, and multilevel interconnect structures (formed at subsequent manufacturing steps).

In some embodiments, a structure includes: a substrate; a transistor structure on the substrate; an interconnect structure coupled to the transistor structure, the interconnect structure including a first metal line; a second metal line in a same metallization layer as the first metal line; and a third metal line in a metallization layer above the first and second metal lines; a first capacitor having a first top electrode and a first bottom electrode; and a second capacitor having a second top electrode and a second bottom electrode, the first and second top electrodes being electrically coupled to the third metal line, and the first and second bottom electrodes being electrically coupled to the first and second metal lines, respectively.

In some embodiments, a method for forming a layout structure of an integrated circuit includes: defining, on a substrate, a first rectangular area corresponding to a first capacitor; defining, on the substrate, a second rectangular area corresponding to a second capacitor; defining, on the substrate, a third rectangular area overlapping the first and second rectangular areas, the third rectangular area corresponding to a metal line; and defining a fourth rectangular area within the third rectangular area and corresponding to a via configured to provide a shared electrical path to the first and second capacitors.

In some embodiments, a method includes: forming first and second metal lines on a substrate; depositing a first inter-layer dielectric (ILD) layer over the first and second metal lines; forming a first trench and a second trench in the first ILD layer and over each of the first and second metal lines; forming a first capacitor and a second capacitor that extend into the first trench and the second trench, respectively, so that bottom electrodes of the first and second capacitors are in physical contact with the first and second metal lines, respectively; depositing a second ILD layer over the first and second capacitors; and forming, in the second ILD layer, a shared contact coupled to top electrodes of the first and second capacitors.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a substrate;
a transistor structure on the substrate;
an interconnect structure coupled to the transistor structure, the interconnect structure comprising:
a first metal line;
a second metal line in a same metallization layer as the first metal line; and
a third metal line in a metallization layer above the first and second metal lines;
a first capacitor having a first top electrode and a first bottom electrode; and
a second capacitor having a second top electrode and a second bottom electrode, the first and second top electrodes being electrically coupled to the third metal line, and the first and second bottom electrodes being electrically coupled to the first and second metal lines, respectively.

2. The structure of claim 1, further comprising a shared via configured to electrically couple the first and second top electrodes to the third metal line.

3. The structure of claim 1, wherein the first and second capacitors are non-planar.

4. The structure of claim 1, wherein the first and second capacitors are T-shaped.

5. The structure of claim 1, wherein the first and second top electrodes and the first and second bottom electrodes comprise titanium nitride.

6. The structure of claim 1, wherein the first and second capacitors comprise a high-k dielectric layer.

7. The structure of claim 6, wherein the high-k dielectric layer comprises a stack of sub-layers.

8. The structure of claim 1, wherein the first and second bottom electrodes are in contact with the first and second metal lines, respectively.

9. The structure of claim 6, wherein the high-k dielectric layer comprises zirconium and aluminum oxide sub-layers.

10. A structure, comprising:
a substrate;
a first rectangular region, corresponding to a first capacitor, disposed on the substrate;
a second rectangular region, corresponding to a second capacitor, disposed on the substrate;
a third rectangular region, corresponding to a metal line, wherein the third rectangular region is disposed on the substrate and overlaps the first and second rectangular regions; and
a fourth rectangular region, corresponding to a via in contact with the first and second capacitors, wherein:
the fourth rectangular region is disposed within the third rectangular region; and
the fourth rectangular region electrically connects the first capacitor to the second capacitor.

11. The structure of claim 10, wherein the first and second capacitors are disposed adjacent to one another.

12. The structure of claim 10, wherein the via is disposed between the first and second capacitors.

13. The structure of claim 10, wherein an area of the third rectangular region is less than or equal to a summation of areas of the first and second rectangular regions.

14. The structure of claim 10, wherein each of the first and second capacitors comprises a high-k dielectric layer with zirconium and aluminum oxide sub-layers.

15. A structure, comprising:
a substrate;
first and second metal lines on the substrate;
a first inter-layer dielectric (ILD) layer disposed over the first and second metal lines;
a first trench and a second trench formed in the first ILD layer and over each of the first and second metal lines;
a first capacitor and a second capacitor that extend into the first trench and the second trench, respectively, wherein bottom electrodes of the first and second capacitors contact the first and second metal lines, respectively;
a second ILD layer deposited over the first and second capacitors; and
a contact, formed in the second ILD layer, coupled to top electrodes of the first and second capacitors and between the first and second capacitors.

16. The structure of claim 15, further comprising:
a third ILD layer deposited over the second ILD layer; and
a third metal line formed in the third ILD layer, wherein the third metal line is coupled to the first and second capacitors through the contact.

17. The structure of claim 16, wherein each of the first and third ILD layers comprises an etch stop layer.

18. The structure of claim 15, wherein each of the first and second capacitors comprises a high-k dielectric layer with zirconium and aluminum oxide sub-layers.

19. The structure of claim 15, wherein the first ILD layer comprises an etch stop layer comprising one or more of silicon carbide (SiC) and silicon nitride (SiN).

20. The structure of claim 15, wherein the first and second capacitors comprise metal layers in the first and second trenches.
